(19) United States
(12) Patent Application Publication
(10) Pub. No.: US 2017/0324425 A1
(43) Pub. Date: Nov. 9, 2017

(54) EMBEDDED PARITY MATRIX GENERATOR

(71) Applicant: Infineon Technologies AG, Neubiberg (DE)

(72) Inventor: Holger Busch, Brunnthal-Otterloh (DE)

(21) Appl. No.: 15/148,599

(22) Filed: May 6, 2016

(51) Int. Cl. H03M 13/11; H03M 13/00

(52) U.S. Cl. CPC H03M 13/1174; H03M 13/616

(57) ABSTRACT

A circuit, including an embedded parity matrix generator configured to generate a parity matrix for a data word of any data width; an encoder configured to add a redundancy word to the data word based on the parity matrix; a sub-circuit coupled to the encoder, and configured to receive the data word and the redundancy word from the encoder; and a decoder coupled to the sub-circuit, and configured to receive the data word and the redundancy word from the sub-circuit, and to detect any errors in the data word based on the parity matrix.

### BACKGROUND

Memories and registers with safety-critical content are safeguarded using error detection and correction. Parity ‘matrices, which describe linear relations that a code word must satisfy, have been derived for individual memories and registers only. Hence, whenever a memory having a new data width is needed, a new parity matrix is derived and added to the chip design, which comprises a collection of predesigned parity matrices for each memory size.

An alternative approach is a predesigned parity matrix having submatrices corresponding to the data width. This approach is simple in that there is only one predesigned parity matrix, but actually employed the submatrices are not optimally balanced except for a few fixed word lengths. Moreover, the submatrices are generally not capable of symmetric code generation.

### BRIEF DESCRIPTION OF THE DRAWINGS

FIG. 1A illustrates a schematic diagram of a circuit in accordance with an aspect of the disclosure.

FIG. 1B illustrates a schematic diagram of a circuit in accordance with another aspect of the disclosure.

FIG. 2 illustrates a schematic diagram of a circuit in accordance with another aspect of the disclosure.

FIG. 3 illustrates a schematic diagram of a circuit in accordance with another aspect of the disclosure.

### DETAILED DESCRIPTION

The present disclosure is directed to a parity matrix generator for any code word width. The parity matrix generator is sufficiently fast to be embedded directly in the encoder and decoder or at a higher level of hierarchy.

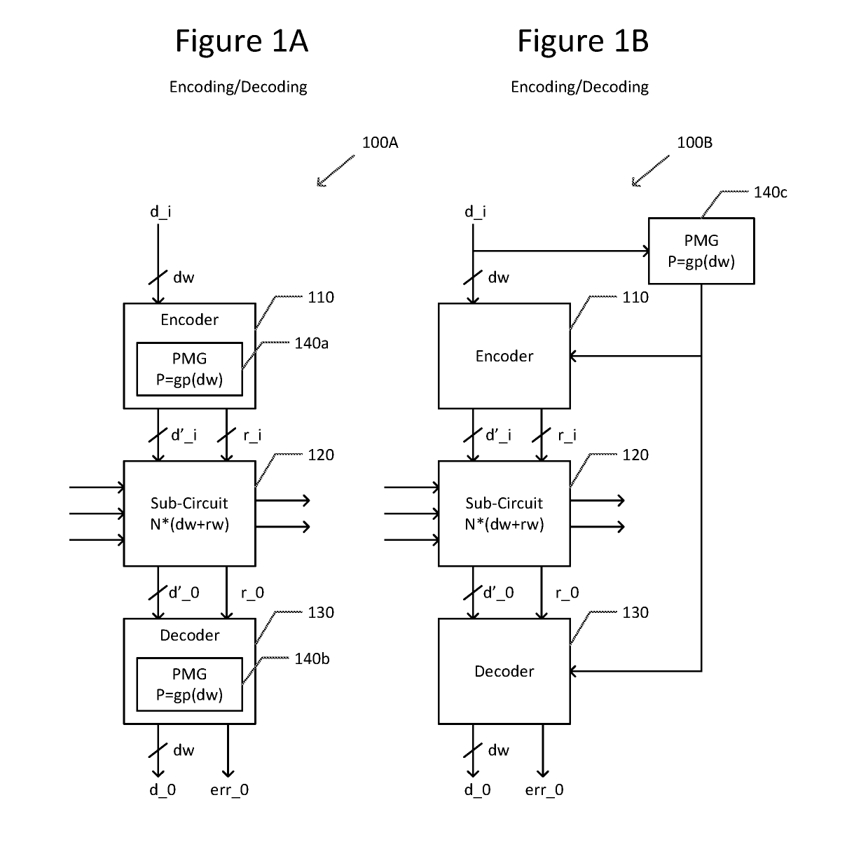

FIG. 1A illustrates a schematic diagram of a circuit 100A in accordance with an aspect of the disclosure. FIG. 1B illustrates a schematic diagram of a circuit 100B in accordance with another aspect of the disclosure. These circuits 100 (100A and 100B) are similar, except for the locations of the embedded parity matrix generator 140, as described below.

The circuit 100 comprises an embedded parity matrix generator 140 (comprising 140a and 140b shown in FIG. 1A, or 140c as shown in FIG. 1B), an encoder 110, a sub-circuit 120, and a decoder 130. The circuit 100 may be located in a microcontroller or any computer system that has protected sub-circuits. The encoder 110 and the decoder 130 may be located in the same, or alternatively, in different areas of a chip. By way of overview, safety-critical memory 120 is embedded in a wrapper with encoder 110 and decoder 120, both being configured with the same parity matrix. For the purposes of this discussion, timing is neglected.

The embedded parity matrix generator 140 is configured to generate a parity matrix for a data word d_i of any data width (dw). The embedded parity matrix generator 140 eliminates a requirement for there to be a predefined parity matrix for each sub-circuit 120, as required in previous protection schemes. The parity matrix generator 140 may be embedded twice in each of the encoder 110 and the decoder 130, as shown in FIG. 1A. Alternatively, the parity matrix generator 140 may be embedded or just once in a wrapper architecture where the resulting parity matrix is fed into the encoder 110 and the decoder 130. A parity matrix is generally defined such that its number of rows corresponds with the data word width, and its number of columns corresponds with the redundancy word width. The embedded parity matrix generator 140 is configured to generate dynamically a parity matrix in accordance with criteria described further below.

The encoder 110 is configured to encode a data word (d_i) into a code word using a parity matrix generated by the parity matrix generator 140. The code word comprises the encoded data word (d_i′) and a redundancy word (r_i). The data word (d_i) may be program data, user data, configuration data, or any other suitable type of data. The redundancy word (r_i) may be, for example, an Error Correcting Code (ECC) word. The parity matrix (P) is generated as a function of the data word (d), that is, P=gp(dw), where dw is data width and gp is a generation function.

The sub-circuit 120 is configured to store the data word (d_i′) and the redundancy word (r_i), though the disclosure is not limited in this respect. The encoder 110 and the decoder 130 may be configured to encode and decode a data word (d_i) transmitted from one point to another without the intervening sub-circuit 120, or with the sub-circuit 120 as a bus. The sub-circuit 120 may be any type of suitable sub-circuit, such as a memory, a register, a bus, an interface, etc. The “N” in the figure represents a depth of the sub-circuit 120. Depth N is N serial synchronization stages, each stage passing dw+rw signals to the next stage and finally to the output of the sub-circuit 120 (i.e., N*(dw+rw)).

The decoder 130 is configured to decode the code word into the data word (d′_o) and the redundancy word (r_o) using the generated parity matrix, which is the same in the encoder 110 and the decoder 130. The decoder 130 is then configured to detect any errors in the data word (d′_o) based on the parity matrix, and optionally to correct any detected errors. The decoder 130 may use the parity matrix to correct single-bit errors, and detect double bit-errors. Triple-bit errors in the data word may be detected without error correction.

With the embedded parity matrix generator 140, no predefined set of parity matrices needs to be provided. This is especially advantageous if a number of data bits to be safeguarded varies in different product derivatives, or if varying frequency requirements enforce modifications of XOR-tree depths of the encoding scheme.

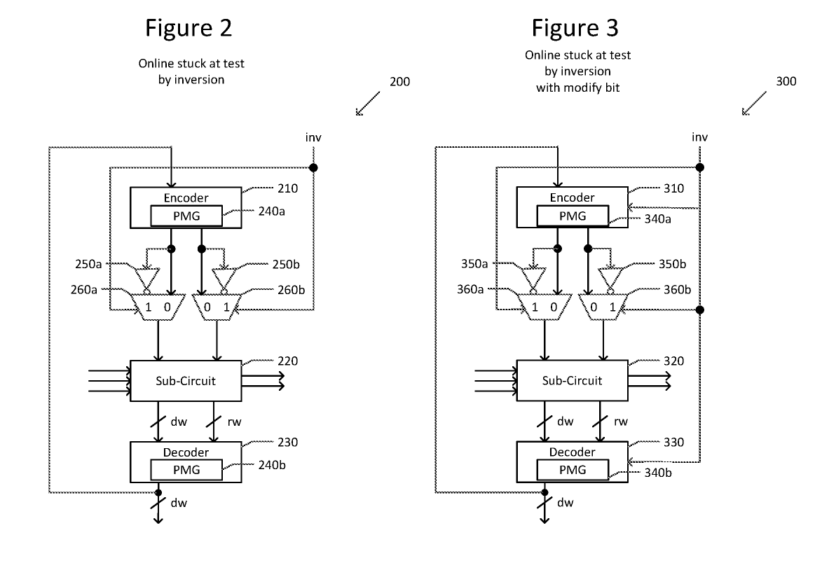

FIG. 2 illustrates a schematic diagram a circuit 200 in accordance with another aspect of the disclosure.

The circuit 200 is similar to the 100 of FIGS. 1A and 1B in that encoder 210 corresponds with encoder 110, sub-circuit 220 corresponds with sub-circuit 120, decoder 230 corresponds with decoder 130, and embedded parity matrix generator 240 corresponds with embedded parity matrix generator 140.

The circuit 200 additionally comprises inverters 250a, 250b and multiplexers 260a, 260b configured to invert the code word (data word+redundancy word). These additional inverter structures serve for self stuck-at testing using a symmetric redundancy code. If single-error correcting and double-error detecting (SECDED) Error Correction Code (ECC) is used, this stuck-at test is capable of detecting up to three stuck-at faults in any combination. During stuck-at testing, normal memory access is blocked, but after testing the original data is available. This is achieved by first reading original data from the sub-circuit 220, writing data after inversion to the memory 120, reading, inverting, and writing the data again, so that the data has finally been inverted twice. The inversion is switched on by a control signal coupled to the multiplexors 260a, 260b, which either negate all data and redundancy code values written and read from the sub-circuit 220 or write the original data. If the redundancy code is symmetric, the decoder 230 and encoder 210 do not need to know the current polarity of the code word. If the redundancy code is asymmetric, the code bits corresponding to matrix columns with even sums have to be additionally inverted in the encoder 210 before write and in decoder 230 after read. Thus it is favorable to use symmetric codes, if possible.

This circuit 200 is further described in U.S. patent application Ser. No. 14/166,360, which was filed Jan. 28, 2014, and is incorporated herein by reference in its entirety.

FIG. 3 illustrates a schematic diagram a circuit 300 in accordance with another aspect of the disclosure.

The circuit 300 is similar to the circuit 200 of FIG. 2 in that encoder 310 corresponds with encoder 210, sub-circuit 320 corresponds with sub-circuit 220, decoder 330 corresponds with decoder 230, the inverters 350 correspond with the inverters 250, the multiplexers 360 correspond with the multiplexers 260, and the embedded parity matrix generator 340 corresponds with embedded parity matrix generator 240.

The circuit 300 additionally comprises an inversion control signal for the addition of a modify-bit, which is indicated by the connection of this signal to encoder 310 and decoder 330. This modification is beneficial for a case in which not all column sums of the parity matrix are odd, that is, the parity matrix is not symmetric. More specifically, the even columns of the matrix are adjusted by a modify-bit. The modify-bit makes these even columns artificially odd, resulting in a same behavior as if the parity matrix were symmetric.

This circuit 300 is further described in U.S. patent application Ser. No. 14/447,806, which was filed Jul. 31, 2014, and is incorporated herein by reference in its entirety.

The parity matrix generator disclosed herein is configured to generate quickly an optimal parity matrix for a range of configuration parameters. The parity matrix generator is configured to provide uniform generic encoder and decoder components generated automatically for any required data word width according to a memory or register size. Aside from data widths, the parity matrix generator is configurable for symmetric SECDED and DED redundant codes, modifiable asymmetric SECDED/DED codes, has a completely equalized or minimized XOR-gate count, minimized or user-defined-limited XOR-tree depth, and increased multiple-bit error detection by incremented code width.

A symmetric matrix has all of its column sums odd, which is a pre-requisite for non-destructive inversion testing without modify-bits. An asymmetric matrix has at least one even column sum.

The parity matrix generation algorithm is based on any of the following criteria:

a) Balancing of ones (1s) in parity matrix columns:

Parity matrix column sums are balanced in any required and feasible way. For example, if a goal is to yield a parity matrix for symmetric code generation, and two columns of an initial parity matrix have even sums, alternative permutations of 1s in matrix rows are computed so that a sum of one column is incremented and a sum of another column is decremented. In order to minimize a maximum depth of XOR-trees for code generation, which is related to a number of 1s in each column of the parity matrix, the 1s are distributed such that a difference of column sums is minimal. This balancing refers to the complete matrix, which can be composed of several submatrices with individual interdependent column sums not necessarily optimally balanced.

b) Parity matrix for symmetric code generation:

A parity matrix generates symmetric code which is used for non-destructive stuck-at testing of memories as described in U.S. patent application Ser. No. 14/166,360, if all of its column sums are odd. In combination with the hamming distances (hd) needed to achieve required error detection capabilities (hd>=2*BEc, where BEc is a number of safely correctable bit errors, and hd>=BE7d−1, where BEd is a number of safely detectable bit errors), a given data word width, and optionally a given code word width, the space of possible solutions for an appropriate parity check matrix is spanned. Moreover, in order to reduce area and power consumption, and combinatorial propagation delays for the encoder 110/210/310 and decoder 130/230/330 circuitry, the parity matrix is constructed such that a total number of XOR-gates, which is related to the number of 1s in the matrix, and a size of the XOR-trees, which is related to the number of 1s in the columns of matrix, are minimized. In addition, it is desirable, but not mandatory to maximize percentages of detectable multi-bit errors for which 100% detection is not required.

c) Generic Register Transfer Level (RTL) components:

An implementation of the matrix generation algorithms in verification environments is possible in any environment and any programming language including hardware description languages like VHDL, or verification languages like SystemC or SystemVerilog. The generation may be provided in a form of configurable RTL components for encoder 110/210/310 and decoder 130/230/330 components which are automatically generated during design elaboration according to direct specification or indirect derivation of generic parameter generations. One component of such generic components is a function for generating appropriately generated parity matrices with all configured properties directly embedded in the generic RTL design. In a verification test-bench, the parity matrix generator eliminates a need for maintaining libraries of matrices for all needed instances by generating currently needed matrices in a dynamic manner, that is, on-the-fly. The parity matrix generator is sufficiently fast so that design elaboration is not noticeably decelerated in comparison with fixed, pre-generated matrices. The obtained negligible generation times of just few seconds for large code word widths even far beyond any practical needs

d) Parity matrix configuration

The dynamic generation of parity matrices is based on a sequence of iterative transformations of intermediate solutions not yet satisfying all requirements. Providing and manipulating these intermediate solutions as explicit matrices are too inefficient. Instead there is matrix configuration that does not uniquely specify one single matrix, but a set of matrices all of which share specific properties. A matrix configuration is defined as a list of 3-tuples C:={{dw₀ k₀ bv₀} . . . {dwᵢ kᵢ bvᵢ} . . . } where each tuple Ci:={dwᵢ kᵢ bvᵢ} specifies a rows-partition of a parity check matrix with

dwᵢ: number of rows of partition i

kᵢ, number of 1s in each row of partition i (row hamming weights)

bvᵢ: balancing vector for the column sums of the sub-matrix corresponding to Cᵢ

The balancing vector specifies the relative differences of column sums C1s of the sub-matrix, where a smaller balancing vector element corresponds to a greater sum of the elements of the corresponding column. Thus the 1s in each matrix are balanced in such a way that the column j with lowest bvᵢⱼ-value has highest column sum. A sub-configuration is not different if a constant is added to all elements of the balancing vector.

Optionally, a column sums vector may be added to the specification of a sub-configuration (just for illustration purposes in this paper): {dwᵢkᵢbvᵢ}:svᵢ

If column sum vector and balancing vector are added, all elements of the result vector are equal.

The specification of the column sums thus does not add any additional constraint but can be uniquely derived from the balancing vector: ∃_{c}∀ᵢc=svᵢⱼ+bvᵢⱼ were c is the minimum value of the balancing vector. If c=0, we call the balancing vector normalized. The sum of the column sums is always given as dwᵢ*kᵢ=ΣᵢSVᵢⱼ.

The concatenation of any selection of sub-matrices corresponding to a list of sub-configurations constitutes a matrix satisfying the overall configuration.

For example, the (sub-)configuration {3 3 {0 0 0 0 1 1}}: {2 2 2 1 1 1} can be implemented by a matrix with the rows {{1 1 1 0 0 0} {1 0 0 1 1 0} {0 1 1 0 0 1}} or alternatively with {{1 1 1 0 0 0} {1 1 0 1 0 0} {0 0 1 0 1 1}}, or others. If all elements of the balancing vector are incremented by a constant, the set of matrices satisfying the configuration does not differ, e.g. {3 3 {1 1 1 1 2 2}}: {2 2 2 1 1 1}. This incrementation may be used for dis-balancing as described later. All matrix solutions of a subconfiguration have in common that each row has 3 1s and their column sums are equal to {2 2 2 2 1}. The sub-configuration {3 5 {0 0 0 1 1 1}}: {3 3 3 2 2 2} has the solution {{1 1 1 0 1 1} {1 1 1 1 0 1} {1 1 1 1 1 0}}. Thus the combined configuration {{3 3 {0 0 0 0 1 1}}: {2 2 2 1 1 1}} {3 5 {0 0 0 1 1 1}}: {3 3 3 2 2 2}}} has the solutions {{1 1 1 0 0 0} {1 0 0 1 1 0} {0 1 1 0 0 1}{1 1 1 0 1 1}{1 1 1 1 0 1} {1 1 1 1 1 0}}, {{1 1 1 0 0 0} {1 1 0 1 0 0}{0 0 1 0 1 1}{1 1 1 0 1 1}{1 1 1 1 0 1}{1 1 1 1 1 0}}, or others.

Any of these combined solutions has a column sum vector {5 5 5 3 3 3} and a corresponding global balancing vector {0 0 0 2 2 2}. It is obvious from this small example that manipulating matrix configurations is far more efficient than using the matrices. For instance, the configuration for a set of parity matrices for data-width 267 is still very handy: {{120 3 {0 0 0 0 0 0 0 0 0 0}} {147 5 {0 0 0 0 0 1 1 1 1 1}}}. In contrast, massaging explicit matrices with 10*267 elements would be much less efficient.

The balancing vector is not arbitrarily selectable: For sub-configurations with invalid balancing vector no solutions exist, e.g. for {3 3 {0 0 0 0 1 1}} or {3 3 {0 2 0 0 0 0}}, or {3 3 {0 0 1 2 3 3}}. In contrast, for {3 3 {0 0 3 2 2 2}} we get a solution: {{1 1 0 1 0 0} {1 1 0 0 1 0} {1 1 0 0 0 1}}. The sum of the column sum vector elements {3 2 1 1 1 1} is bound to be dwᵢ*kᵢ=3*3=9.

The code width is reflected by the length of the balancing vectors: rw=length(bvᵢ) for any i, which directly corresponds to the number of columns of the parity check matrix. For each sub-configuration the number of sub-matrix rows is limited by the inequality:

$${dw}_{i} <= ( \begin{matrix}rw \\ {k}_{i}\end{matrix} )$$

For instance, {dwₘₐₓ(5), 3 {0 0 0 0 0}} configures a complete sub-matrix with

$${dw}_{max} ( 5 ) = ( \begin{matrix}5 \\ 3\end{matrix} ) = 10$$

different rows with all unique permutations of 3 1-positions.

e) Constrained parity matrix configuration

A constrained parity matrix configuration includes an additional constraint pattern in each subconfiguration, and is specified as list of 4-tuples with {dwᵢ patᵢ ki bvᵢ}. The constraint pattern specifies that all rows of the sub-configuration satisfy the pattern. The balancing vector here refers only to the unconstrained positions, thus has length(bvᵢ)=rw−rwlᵢ, with rwlᵢ:=number(constrained columns), as obviously it would not make sense to include the fixed constrained positions, for which no balancing is possible. If the constraint pattern constrains rwlᵢ, row positions, the number of sub-matrix rows is dwᵢ<=(rw−rwlᵢkᵢ).

For example, the {3, {* * * 0 *}, 3, {1 0 1 1}} configuration is satisfied by the matrix {{1 1 1 0 0} {1 1 0 0 1} {0 1 1 0 1}}, and the maximum configuration would be given as {4, {* * * 0 *}, 3, {0 0 0 0}} with one additional matrix row {1 0 10 1}.

An unconstrained configuration according to c) can be considered as a constrained configuration with the non-constraining pattern {*}.

The validity of a constrained sub-configuration directly follows from the validity of the unconstrained configuration corresponding to the tuple elements without constraint pattern.

If the constraint is specified by a pattern with wild-cards for unconstrained positions, the validity of the sub-configuration is automatically given if the unconstrained sub-configuration is valid.

Constraints could alternatively be specified as logical functions of row bits, e.g. “if bit 1=1 then bit 3=0”. In this case the sub-configuration could be split into several pattern-constrained subconfigurations with the patterns: {* * * 1 0},{* * * 0 *}, or alternatively: {* * * 1 O},{* * * 0 0},{* * * 0 1}.

For the sake of conciseness, right-most coherent wild-card positions can be omitted, i.e. {* 0 * * *}˜>{* 0}, {1 * *}˜>{1}. When constrained sub-configurations with constraint patterns of different length are combined to constrained configurations, those with constraints with smaller length are split in their wild-card positions until all patterns have same length, e.g.: {1 *}˜>{1 0} {1 1}, where the resulting data widths dwᵢ₀ and dwᵢ₁, and balancing vectors bvᵢ₀ and bvᵢ₁ are computed in an appropriate way described below.

f) Balancing and dis-balancing

A sub-configuration with a balancing vector with a difference of at most 1 between minimal and maximum element is a balanced sub-configuration. All permutations of the balancing vector also result in balanced sub-configurations. A balanced sub-configuration may equivalently be specified by replacing the balancing vector in the tuple with the code width: {dwᵢ patᵢ kᵢ rw}.

A balancing-vector with minimal element 0 is a normalized balancing vector.

A balancing-vector with a difference>1 between minimal and maximal element is a disbalancing vector. If this difference is 2, the dis-balancing level is 1, generally n−1 for difference n. In addition, a dis-balancing index denotes the number of increment-/decrement steps performed for dis-balancing. It can be computed by sorting normalized balancing and dis-balancing vector and computing a vector with absolute element-wise differences. disbalance(bv,n,m) is written for a transformation of default balanced configuration if the maximum difference between highest and lowest element of the balancing vector (or corresponding column sums) is n and m disbalancing steps have been performed. disbalance(bv,n,m,c) is written if a constant c is added to all elements of the normalized balancing vector, the difference between its smallest and greatest elements is n+1, and the sum of all positive elements of the difference vector between balancing vector and disbalanced vector is m.

The following are a few examples:

disbalance({1 1 1 1 10 0},0,0,0)={1 1 1 1 10 0}

disbalance({1 1 1 1 10 0},0,0,1)={2 2 2 2 2 1 1}

disbalance({1 1 1 1 10 0},0,0,2)={3 3 3 3 3 2 2}

disbalance({1 1 1 1 10 0},1,1,0)={2 1 1 1 0 0 0}

disbalance({1 1 1 1 10 0},1,2,0)={2 2 1 0 0 0 0}

disbalance({1 1 1 1 10 0},1,1,1)={2 2 2 2 2 2 0}

disbalance({1 1 1 1 10 0},2,1,1)={3 2 2 2 2 1 0}

disbalance({1 1 1 1 10 0},2,2,1)={3 3 2 2 1 1 0}

A balanced configuration has a solution for sufficient code width, whereas dis-balanced configurations may have no solution. If a dis-balanced configuration has no solution, then a configuration even more dis-balanced has not either. This relationship suggests to iteratively increase the dis-balancing if needed, starting from a valid balanced configuration.

g) Multi-Balancing

In order to satisfy a global balancing vector for an entire configuration, the balancing vectors of the sub-configurations are determined in such a way, that their joint column sums correspond to the global balancing vector. The dis-balancing level of each individual balancing vector is never higher than the dis-balancing level of the global balancing vector. Often, global dis-balancing can be achieved without dis-balancing. By multi-balancing, we are able to generate balancing vectors for sub-configurations of a configuration in order to satisfy a given global balancing vector of the complete configuration. For instance for a list {{dw₀ k₀} {dw₁ k₁}}:={{2 2} {5 3}} and a global balancing vector bvg:={0 0 3 0 3}, the configuration {{2 2 {0 1 2 1 2}}:2 1 0 1 0 {5 3 {0 0 2 1 2}}:4 4 2 3 2} is obtained.

Below, sets of functions are summarized which in total constitute the system of embedded matrix generation functions inserted into the generic encoder and decoder components.

h) A set of matrix generators for:
transforming an unconstrained sub-configuration {dwᵢ kᵢ bvᵢ} into a parity check matrix with dwᵢ rows, all of which with hamming weight kᵢ, and where the vector of its column sums added to its balancing vector bvᵢ results in a vector with identical elements.
transforming a constrained sub-configuration {dwᵢ patᵢ kᵢ bvᵢ} into a parity check matrix where the constrained columns contain only 0s or only 1s depending on the constraint pattern. In fact, this function first invokes the previous function for the unconstrained columns, then adds 0-, and 1-columns according to the constraint pattern.
transforming a configuration with sub-configurations into a parity check matrix by simply concatenating the sub-matrices yielded by application of the first function to the subconfigurations.
transforming a constrained configuration with constrained sub-configurations into a parity check matrix by simply concatenating the sub-matrices yielded by application of the second function to the constrained sub-configurations.

i) A set of configuration generators for:
computing the default configuration for a given payload data width, matrix row hamming distance, and an optional code width>=the minimum required. For instance, a (Hsiao-) parity matrix for SECDED requires a row hamming distance>=2, with a minimum of 3 1s per row.
computing a configuration with sub-configurations for odd k>=3
computing a configuration with sub-configurations for odd and even k>=3
computing an invertible configuration with sub-configurations with odd k>=3, by transforming an initial non-invertible configuration into an invertible one, which is not always possible without increasing the code width.
computing an invertible configuration with sub-configurations for odd and even k>=3, which allows in many cases an incremented code width to be avoided.

j) A set of configuration transformation functions for:
increasing dwᵢ, of sub-configuration i by δ_{+dwi} and decreasing dwⱼ of sub-configuration j by δ_{-dwi} such that

$${\sum }_{i} {δ}_{+ dwi} = {\sum }_{j} {δ}_{- dwj} .$$

Such transformations change the global balancing vector of the complete configuration, which is intended, if e.g. the number of even column sums cannot be modified in the required way by balancing or dis-balancing individual sub-configurations only without touching their data widths.
computing transformation specifications {δ_{+dwi0}, . . . , δ_{+dwim}, δ_{-dwj0}, . . . δ_{+dwjn}} with

$${\sum }_{i} {δ}_{+ dwi} = {\sum }_{j} {δ}_{- dwj} .$$

such that the global balancing vector bv_{g}:={bv_{g}^{rw-1}, bv_{g}^{rw-2}, . . . bv_{g}⁰} is modified in a specific required way to bv_{g}:={bv_{g}^{′rw-1}, bv_{g}^{′rw-2}, . . . bv_{g}^{′0}} For instance, modifying a configuration {{dwᵢ, kᵢ, bvᵢ,{0}}, {dwⱼ, kⱼ, bvⱼ,{1}} to {{dwᵢ−1, kᵢ, bvᵢ,{0}},{dwⱼ+1, kⱼ, bvⱼ,{1}} will increase the leftmost column sum by 1, and accordingly decrease the leftmost component of the resulting global balancing vector by 1 to bv′_{g}:={bv_{g}^{rw-1}, bv_{g}^{′rw-2}, . . . bv_{g}^{′0}}, where the righter components of the new global balancing sub-vector have to be recomputed.

k) A set of auxiliary functions for:
computing the vector of (left-right-partitioned) column sums related to a (constrained) matrix configuration
computing the vector of (left-right-partitioned) column sums related to a list of matrix configurations
transforming column sum vectors into balancing vectors.
computing the global balancing vector of a configuration from its sub-configurations.
computing the vector of even-odd-indicators related to column sum vectors, and the number of (partitioned) even columns sums
computing the maximum number of (pay-load) data bits for a given code width and row hamming distance or the minimum code width for a given data width
testing a configuration for the non-existence of a solution according to the following lemmas:

1. A solution for the balanced default configuration (with sufficient code width) always exists.

2. A solution does not exist for a configuration which cannot be transformed into a balanced configuration by iteratively reducing one selected position of the balancing vector and increasing another position by the same difference. For example, if the balancing vector {0 0 0 0 1} pertains to a configuration, a solution may not exist for {0 2 0 2 2}, but definitely does not exist for {1 0 0 0 1}.

3. A solution does not exist for disbalance(n,m,c), if n+m>dw, or if the difference between maximum data width corresponding to the code width and given data width is smaller than n: n+m>dwmax(rw)−dw. For instance, the configuration{3, 3, {0 0 0 0 1}} cannot be transformed into {3, 3, {0 4 0 2 0}}.

4. If a solution exists for a configuration, any configuration with arbitrarily permuted balancing vector has a solution.

5. No solvable invertible configuration with only odd row hamming weights exists if the number of even column sums is odd. This is a powerful and simple criterion for deciding whether the generator for odd-even matrix row weights is invoked.

6. If no disbalance(n0,m0,c0) solution exists, disbalance(n1,m1,c1) does not have a solution either if n1+m1>n0+m0.

These lemmas provide fast tests for the existence of solutions of sub-configurations. Another potentially more expensive test recursively derives the existence of a solution of a configuration from the existence of solutions for the two sub-configurations which result from splitting the configuration {dwᵢ, kᵢ, bvᵢ,{*}} into 2 constrained parts with constraint patterns {dwᵢ₀{0} kᵢ₀ bvᵢ₀} and {dwᵢ₁ {1} kᵢ₁ bvᵢ₁}. For this purpose, a multi-balancing function for splitting a configuration into valid sub-configurations has been provided. If being used for checking the validity of a configuration, the recursive investigation of the validity of a configuration is stopped when all its sub-configurations have balancing vectors with 0-1 only, which are valid according to Lemma 1.

The ordering of tests according to their complexity is crucial for an efficient construction procedure for a configuration with at least one solution with the required properties.

l) A set of configuration transformation functions for
increasing dwᵢ of sub-configurations i by δ_{+dwi} and decreasing d_{wj} of sub-configurations j by δ_{-dwj} such that

$${\sum }_{i} {δ}_{+ dwi} = {\sum }_{j} {δ}_{- dwj} .$$

such transformations change the global balancing vector of the complete configuration, which is intended, if e.g. the number of even column sums cannot be modified in the required way by balancing or dis-balancing individual sub-configurations only without balancing their data widths.
computing transformation specifications {δ_{+dwi0}, . . . , δ_{+dwim}, δ_{-dwj0}, . . . δ_{+dwjn}} with

$${\sum }_{i} {δ}_{+ dwi} = {\sum }_{j} {δ}_{- dwj} .$$

such that the global balancing vector bv_{g}:={bv_{g}^{rw-1}, bv_{g}^{rw-2}, . . . bv_{g}⁰} is modified in a specific required way to bv_{g}:={bv_{g}^{′rw-1}, bv_{g}^{′rw-2}, . . . bv_{g}^{′0}} For instance, transforming a configuration {{dwᵢ, kᵢ, bvᵢ,{0}}, {dwⱼ, kⱼ, bvⱼ,{1}} to {{dwᵢ−1, kᵢ, bvᵢ,{0}},{dwⱼ+1, kⱼ, bvⱼ,{1}} will increase the leftmost column sum by 1, which may make it odd, and accordingly decrease the leftomost component of the resulting global balancing vector by 1 to bv′_{g}:={bv_{g}^{rw-1}, bv_{g}^{′rw-2}, . . . bv_{g}^{′0}}, where the righter components of the new global balancing sub-vector have to be recomputed.

m) A set of configuration generators for:
computing the default configuration for a given payload data width, matrix row hamming distance, and an optional code width>=the minimum required. For instance, a (Hsiao-) parity matrix for SECDED requires a row hamming distance>=2, with a minimum of 3 1s per row.
computing a configuration with sub-configurations for odd k>=3
computing a configuration with sub-configurations for odd and even k>=3
computing an invertible configuration with sub-configurations for odd k>=3, by transforming an initial non-invertible configuration into an invertible one, which is not always possible without increasing the code width.
computing an invertible configuration with sub-configurations for odd and even k>=3, which allows in some cases an incremented code width to be avoided.

n) Complete decision procedure for validity of configuration

A sub-configuration is called valid if at least one satisfying sub-matrix exists, and a configuration composed of several sub-configurations is valid if all its sub-configurations are valid.

Accordingly, the validity of a configuration is recursively derived from the validity of the subconfigurations for the left-most 1 and the left-most 0 rows: V{dwᵢ kᵢ bvᵢ}:=V{dw1ᵢ {1} k1ᵢ bv1ᵢ}/\ V{dw0ᵢ{0} k0ᵢ bv0ᵢ pat0ᵢ} where:

dw1ᵢ:=C1s({dwᵢ, kᵢ, bvᵢ,}rw−1), i.e. the sum of the left most column (index rw−1);

dw0ᵢ:=dwᵢ−dw1ᵢ; k1ᵢ:=kᵢ−1; k0ᵢ:=kᵢ pat1ᵢ:={1}, pat0ᵢ:={0},

The balancing vectors bv1ᵢ and bv0ᵢ are generated by the multi-balancing procedure cfgdbvs which computes valid sub-configurations from given lists of {dwᵢ, kᵢ} pairs and a global balancing vector, which in this special case corresponds to the original balancing vector without its leftmost element, so we obtain: cfgdbvs {{dw1ᵢ k1ᵢ}{dw0ᵢ k0ᵢ}} bvᵢ(rw−2 . . . 0)={{dw1ᵢ k1ᵢ bv1ᵢ} {dw0ᵢ k0ᵢ bv0ᵢ}}

The validity of the configuration {3, 3, {0 0 0 0 1}} follows from the validity of the 1-sub-configuration which has 2 rows with {2,2,{0 0 0 0}} and a 0-sub-configuration which has 1 row {1 3 {0 0 0 1}}.

Advantages of this disclosure are numerous. The summarized procedures generate parity check matrices with optional inversion capability for arbitrary data word and code widths.

According to different optimization criteria, such as XOR-gate count, XOR-tree depth, code width, multiple bit detection, provably optimal solutions are generated. This is guaranteed by starting from a minimum solution which initially does not meet all requirements, and gradually transforming the matrix configuration just with the minimum number of steps needed to yield a solution satisfying all constraints.

The concept of matrix configurations and prioritized validity checks allows very concise and fast transformations with backtracking to be performed, before the final explicit matrix solution is generated.

After selection of parameters (only if the default settings are not being used), no human interaction is required, all generation happens automatically for any set of parameters directly derivable from memory or register sizes.

Rather than a set of many different approaches for different requirements, uniform comprehensive generic functions and encoder and decoder components are provided.

The recursive generation algorithms are kept concise by reducing intermediate tasks to sub-tasks already covered by basic functions. For instance, the function for checking the validity of unconstrained sub-configurations is recursively applied when a sub-configuration is split into a sub-sub-configuration with leading all-1s column and a sub-configuration with leading all-0s column.

For this purpose a more general function has been devised which computes (dis-) balancing vectors of any number of sub-configurations in order to satisfy a global balancing vector.

Different options are directly accessible to module designers who just need to select different generic parameters for the included pre-defined RTL components, in order to optimize the generated error handling circuitry according to different criteria to be judged on the ground of area and static timing analyses at module level. If a module is run at high frequency, the module designer can, for example, configure the maximum XOR-depth to a limit which ensures that combinatorial paths do not exceed the maximum delay still processable in one clock cycle. If area is an issue, the matrix with minimum total number of ones is the best option. Safety analyses may well result in new requirements, which can be matched by corresponding re-configurations that do not require extra effort than just selecting different parameter sets.

The following is a more detailed look at generation of parity matrices for SECDED protection. A parity matrix is generated only after a configuration with all desired properties has been determined. The following construction steps are performed to generate an invertible matrix for a data width of 128 and an ECC width of 9.

Step a)

The construction of a configuration starts with a quick test to determine whether an initial default (Hsiao) configuration with odd row weights starting from 3 can at all have an invertible solution: No solution exists if:

$$( ( {\sum }_{i}^{2 * i + 3 \leq rw} {dw}_{i} * {k}_{i} ) / rw ) / \%2 = 1 and ( ( {\sum }_{i}^{2 * i + 3 \leq rw} {dw}_{i} * {k}_{i} ) / rw ) / \%2 rw ) \%2 = 1 or ( ( {\sum }_{i}^{2 * i + 3 \leq rw} {dw}_{i} * {k}_{i} ) / rw ) / \%2 = 0 and rw - ( {\sum }_{i}^{2 * i + 3 \leq rw} {dw}_{i} * {k}_{i} ) \% rw ) \%2 rw ) \%2 = 1$$

with kᵢ:=2*i+3, where kᵢ≦rw;

$$Cfg0\_ 128 \_ 9 := \{ \{ ( \begin{matrix}9 \\ 3\end{matrix} ) , 3 , 9 \} \{ 128 - ( \begin{matrix}9 \\ 3\end{matrix} ) , 5 , 9 \} \} = \{ \{ \begin{matrix}84 & 3\end{matrix} \{ \begin{matrix}0 & 0 & 0 & 0 & 0 & 0 & 0 & 0 & 0\end{matrix} \} \text{:} \{ \begin{matrix}28 & 28 & 28 & 28 & 28 & 28 & 28 & 28 & 28\end{matrix} \} \{ \begin{matrix}44 & 5\end{matrix} \{ \begin{matrix}0 & 0 & 0 & 0 & 1 & 1 & 1 & 1 & 1\end{matrix} \} \text{:} \{ \begin{matrix}25 & 25 & 25 & 25 & 24 & 24 & 24 & 24 & 24\end{matrix} \} \} ,$$

and where x % n here denotes the modulo −n function, x/n integer division by n.

For example, there is no solution for 128 data bits with an ECC width of 9:

$${dw}_{i} := max ( 0 , min ( ( \begin{matrix}rw \\ {k}_{i}\end{matrix} ) , dw - {\sum }_{j = 0}^{j < i} {dw}_{j} )$$

with following column sums:

{53 53 53 53 52 52 52 52 52}.

As 5 of them are even, this non-invertible cannot be transformed into an invertible solution, because for each 3-row being replaced by a 5-row, 2 ones are added, so that the number of even column sums is still odd. The initial solution can be transformed at most into a solution with 8 odd, but not with 9 odd columns sums, e.g., with the configuration

{{84 3 {0 0 0 0 0 0 0 0 0}:{28 28 28 28 28 28 28 28 28}

{44 5 {0 0 0 0 0 0 1 2 2}:{25 25 25 25 25 25 24 23 23}}, which produces the following column sums: {53 53 53 53 53 53 52 51 51}.

In contrast, for a data word-length of 127, the default configuration

$$Cfg0\_ 127 \_ 9 := \{ \{ ( \begin{matrix}9 \\ 3\end{matrix} ) , 3 , 9 \} \{ 127 - ( \begin{matrix}9 \\ 3\end{matrix} ) , 5 , 9 \} \} = \{ \{ 84 , 3 , \{ \begin{matrix}0 & 0 & 0 & 0 & 0 & 0 & 0 & 0 & 0\end{matrix} \} \{ 43 , 5 , \{ \begin{matrix}0 & 0 & 0 & 0 & 0 & 0 & 0 & 0 & 1\end{matrix} \} \} \}$$

has an even number of even column sums: {52 52 52 52 52 52 52 52 51} and can thus be made invertible by dis-balancing the second sub-configuration with dis-balancing vector: {0 0 0 0 2 2 2 2 2}, which results in Cfg1_127_9:={{84,3, {0 0 0 0 0 0 0 0 0} {43, 5, {0 0 0 0 2 2 2 2 2}}} with the column sums: {53 53 53 53 51 51 51 51 51}. Generally by dis-balancing, the total number of 1s in the matrix is not modified. Alternatively, an invertible configuration could also have been obtained by replacing 5 3-rows with 5 5-rows, hence increasing the total number of ones by 5*2=10: Cfg2_127_9:={{79 3 {0 0 0 1 1 1 1 1 1}{48 5 {0 0 0 0 0 0 1 1 1}}} which corresponds to columns sums {54 54 54 53 53 53 52 52 52}. Even though this configuration is not yet invertible, no disbalancing is required here, but mutual re-balancing sufficient:

Cfg2_127_9:={{79 3 {0 0 0 1 1 1 1 1 1}:127 27 27 26 26 26 26 26 261{48 5 {1 1 1 0 0 0 0 0 0}:{26 26 26 27 27 27 27 27 27}}, in order to achieve equal column sums of 53 each.

The evaluation of configuration Cfgo_12δ_9 shows that no symmetric solution with odd row weights exists for data with 128 protected by ECC bits.

Step b)

For this reason, there is another algorithm which adds rows with even weights. However, in order to keep the hamming distances of the matrix rows at the minimum required for the same fault correction and detection capability as odd-weight solutions, additional constraints are imposed. Without affecting the universality of the approach, but for the sake of easier understandability, constraints on the three left-most matrix columns are exemplified.

Rows with an odd number of row weights>=3 are constrained with the combinations {0 0 0}, {0 0 1}, {0 1 0}, {1 0 0} in their left-most positions. Rows with an even number of row weights>=4 have {1 1 1} in their left-most positions. This construction guarantees that all rows with Hamming weight k have a Hamming distance of at least 2 from all rows with Hamming weight k−1 and from all rows with weight k+1, which is sufficient for 2-bit error detection/1-bit error correction. Hamming distance>1 between rows with k and k+2 ones is also guaranteed for even kᵢ as the 3 right-most row positions have k−3 and k−1 ones. For odd kᵢ in the worst case k-rows would have k ones in the ew−3 right-most positions, and k+2−1=k+1 ones in the ew−3 right-most positions. Even though right subrows would have only Hamming-distance 1, this is compensated by the fact that this scenario only arises if k-rows have constraint pattern {0 0 0} and k+2-rows constraint patterns {0 0 1}, {0 1 0}, or {1 0 0}. Thus in this case, the left sub-rows increase the Hamming distance to the required minimum of 2.

Step c) The algorithm for generating even solutions performs the following steps:

Step c1) An initial minimal solution is generated with constraint odd- and even-k-weight partitions:

Starting from 2k+1=3, the constrained odd sub-configurations

{dw_{2k+1,{0 0 1}}{0 0 1}2k+1 bv_{2k+1,{0 0 1}}},

{dw_{2k+1,{0 1 0}}{0 1 0}2 k+1 bv_{2k+1,{0 1 0}}},

{dw_{2k+1,{1 0 0}}{1 0 0}2k+1 bv_{2k+1,{1 0 0}}},

{dw_{2k+1,{0 0 0}}{0 0 0}2k+1 bv_{2k+1,{0 0 0}}},

are generated with

$${dw}_{2 k + 1 \{ \begin{matrix}0 & 0 & 0 \}\end{matrix}} <= ( \begin{matrix}ew - 3 \\ 2 k + 1\end{matrix} ) , {dw}_{2 k + 1 \{ \begin{matrix}0 & 0 & 1 \}\end{matrix}} <= ( \begin{matrix}ew - 3 \\ 2 k\end{matrix} ) ,$$

and dw_{2k+1{0 1 0}}, and dw_{2k+1{1 0 0}} correspondingly.

Starting from 2k+2=4, the constrained sub-configurations

{dw_{2k+2,{1 1 1}}{1 1 1}2k+2bv_{2k+2,{1 1 1}}} with

$${dw}_{2 k + 2 \{ \begin{matrix}1 & 1 & 1 \}\end{matrix}} <= ( \begin{matrix}ew - 3 \\ 2 k - 1\end{matrix} )$$

are generated until the sum of all dwₖ equals the required total data width dw.

This construction yields a configuration for a matrix with minimum total number of ones, which normally is not yet symmetric.

Step c2) The initial configuration is transformed, if necessary, in such a way that it has at least an even number of even column sums, in the best case already 0. While such a transformation is impossible with a pure odd-k configuration, the required effect is here achieved by incrementing some dwₖᵢ and decrementing some dwₖⱼ where ki is odd and kj is even, or conversely. Additionally the exchange pairs are selected in such a way that the sums of all constrained columns, in our setting the three left-most ones, are all odd. A specific subroutine selects possible sub-configurations to be incremented and others to be decremented, so that the sum of increments exactly equals the sums of decrements in order to preserve the overall required sum dw of all data widths of all subconfigurations.

Step c3) The left-symmetric configuration resulting from 2. is now transformed into a fully symmetric configuration by (dis-)balancing unsaturated sub-configurations against each other. For this, the procedure already used for the purely odd sub-configurations is re-used.

If no such totally-symmetric solution exists, corresponding pairs of dwk and dwk+n*2 with same constraint pattern are in-/decremented. By this it is achieved that the symmetry of the constrained columns is preserved. The resulting configuration is then fully symmetric.

Step c4) In order to minimize the maximum column sums, an optional extra transformation is performed. It reduces the column sums of the right part by increasing the column sums of the left part in such a way that the overall symmetry is preserved. This effect is achieved by replacing an even number of {0 0 0}-, {0 0 1}-, {0 1 0}-, or {1 0 0}-rows by the same number of {1 1 1} rows with next higher row weight. By each 2*{0 0 0},2k+1->2*{1 1 1},2k+2 exchange, the sum of all left columns in total is incremented by 6, and the sum of all right columns totally decremented by 4.

By each 2*{0 0 1},2k+1->2*{1 1 1},2k+2 exchange, the sum of all left columns in total is incremented by 4, and the sum of all right columns totally decremented by 2.

By exchanging only equal odd-weighted rows 2*{0 0 0},2k+1->2*{0 0 1},2k+1, 2*{0 1 0},2k+1, or 2*{1 0 0},2k+1, the sum of all left columns in total is incremented by 2, and the sum of all right columns totally decremented by 2.

Step d) The following table shows the maximum data word widths protectable by minimum ECC widths (ew).

TABLE 1
Data Width Ranges for Even/Odd Symmetric Solutions

| ew | dwmax | dwevmax | dwev0 | dwev1 |
|---|---|---|---|---|
| 5 | 11 | 5 | — | — |
| 6 | 26 | 14 | — | — |
| 7 | 57 | 33 | 28 | 28 |
| 8 | 120 | 72 | 59 | 67 |
| 9 | 247 | 151 | 122 | 146 |
| 10 | 502 | 310 | 249 | 305 |
| 11 | 1013 | 629 | 504 | 624 |
| 12 | 2036 | 1268 | 1015 | 1263 |
| 13 | 4083 | 2547 | 2038 | 2542 |
| 14 | 8178 | 5106 | 4085 | 5101 |
| 15 | 16369 | 10225 | 8180 | 10220 |
| 16 | 32752 | 20464 | 16371 | 20459 |
| 17 | 65519 | 40943 | 32754 | 40938 |
| 18 | 131054 | 81902 | 65521 | 81897 |
| 19 | 262125 | 163821 | 131056 | 163814 |
| 20 | 524268 | 327660 | 262127 | 327655 |

For data widths dw in the range dwmax(ew−1)<=dw<=dwevmax(ew), an ecc width ew is theoretically sufficient even for an even invertible solution, if no odd invertible solution exists.

However, due to other constraints for disbalancing, an even invertible solution may not exist in some cases. Conversely, for data-widths in the range dwevmax(ew)<dw<=dwmax(ew) no even invertible solution exists with ECC with ew, if no invertible odd solution exists. In this case, ew has to be incremented by 1, which always enables an invertible solution.

In column dwev0, the actual minimum dw is given for which an even solution is used if no odd (Hamming-weights) solution exists. In column dwev1, the actual maximum dw is shown, i.e. for all greater dw for which no odd solution exists, ew has to be inevitable incremented by 1.

While the foregoing has been described in conjunction with exemplary embodiment, it is understood that the term “exemplary” is merely meant as an example, rather than the best or optimal. Accordingly, the disclosure is intended to cover alternatives, modifications and equivalents, which may be included within the scope of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This disclosure is intended to cover any adaptations or variations of the specific embodiments discussed herein.

What is claimed is:

1. A circuit, comprising:
an embedded parity matrix generator configured to generate a parity matrix for a data word of any data width;
an encoder configured to add a redundancy word to the data word based on the parity matrix;
a sub-circuit coupled to the encoder, and configured to receive the data word and the redundancy word from the encoder; and
a decoder coupled to the sub-circuit, and configured to receive the data word and the redundancy word from the sub-circuit, and to detect any errors in the data word based on the parity matrix.

2. The circuit of claim 1, wherein the sub-circuit is selected from a group of sub-circuits consisting of a memory, a register, a bus, and an interface.

3. The circuit of claim 1, wherein the parity matrix generator is embedded in both the encoder and the decoder.

4. The circuit of claim 1, wherein the decoder is further configured to correct the data word based on the parity matrix.

5. The circuit of claim 1, wherein the parity matrix generator is further configured to generate the parity matrix to enable the decoder to correct any single-bit errors in the data word, to detect any double bit-errors in the data word, and to detect but not correct up to three bit errors.

6. The circuit of claim 1, wherein the parity matrix generator is further configured to generate the parity matrix with a minimum number of modify-bits allowing the width of the data word plus redundancy word to be equal to a parity matrix that is balanced and asymmetric.

7. The circuit of claim 1, wherein the parity matrix generator is further configured to generate the parity matrix to comprise column sums balanced according to a balancing vector.

8. The circuit of claim 1, wherein the parity matrix generator is further configured to perform a fast test for feasibility of a balancing or dis-balancing specification for column sums of the parity matrix.

9. The circuit of claim 1, wherein the parity matrix generator is further configured to generate the parity matrix to comprise column sums balanced according to a balancing vector and dis-balancing of column sums to differences greater than one.

10. The circuit of claim 1, wherein the parity matrix generator is further configured to compute automatically a minimum required width of the redundancy word.

11. The circuit of claim 1, wherein the parity matrix generator is further configured to generate the parity matrix to be symmetric.

12. The circuit of claim 1, wherein the parity matrix generator is further configured to generate the parity matrix to be symmetric with constrained sub-matrices having odd and even row Hamming weights, and having a same code word width as the parity matrix when in asymmetric form.

13. The circuit of claim 1, wherein the parity matrix generator is further configured to generate the parity matrix to be symmetric by adding a minimum number of ones to an asymmetric parity matrix while preserving a data width.

14. The circuit of claim 13, wherein the party matrix generator is further configured to balance the parity matrix by adding ones to the parity matrix until the parity matrix has an xor-tree depth that is less than a predetermined limit.

15. The circuit of claim 14, wherein the party matrix generator is further configured to increase a width of the redundancy word by just enough so that xor-tree depths are below a predetermined value.

16. The circuit of claim 1, wherein the parity matrix generator is further configured to generate the parity matrix having a predefined set of row Hamming weights.

17. A method, comprising:
generating, by an embedded parity matrix generator, a parity matrix for a data word of any data width;
adding, by an encoder, a redundancy word to the data word based on the parity matrix;
receiving, by a sub-circuit coupled to the encoder, the data word and the redundancy word from the encoder;
receiving, by a decoder coupled to the sub-circuit, the data word and the redundancy word from the sub-circuit; and
detecting, by the decoder, any errors in the data word based on the parity matrix.

18. The method of claim 17, further comprising:
generating, by the parity matrix generator, two sub-matrices with leading-one-rows and leading-zero-rows; and
recursively balancing, by the parity matrix generator, the parity matrix into a balanced parity matrix.

19. The method of claim 17, wherein the generating the parity matrix step comprises:
recursively generating constrained sub-configurations with individual sub-data widths, row-Hamming weights, balancing vectors, and constraint patterns.

20. The method of claim 17, wherein the generating the parity matrix step comprises:
repartitioning sub-matrices with different row-Hamming weights and/or constraint patterns; and
multi-balancing the sub-matrices,
wherein an initial asymmetric parity matrix is transformed into a symmetric parity matrix.
